(19) United States
(12) Patent Application Publication
(10) Pub. No.: US 2013/0183814 A1
(43) Pub. Date: Jul. 18, 2013

(54) METHOD OF DEPOSITING A SILICON GERMANIUM TIN LAYER ON A SUBSTRATE

(71) Applicant: APPLIED MATERIALS, INC., Santa Clara, CA (US)

(72) Inventors: YI-CHIAU HUANG, Fremont, CA (US); ERROL ANTONIO C. SANCHEZ, Tracy, CA (US)

(73) Assignee: APPLIED MATERIALS, INC., Santa Clara, CA (US)

(21) Appl. No.: 13/736,417

(22) Filed: Jan. 8, 2013

Related U.S. Application Data
(60) Provisional application No. 61/586,181, filed on Jan. 13, 2012.

(51) Int. Cl. H01L 21/02

(52) U.S. Cl. CPC H01L 21/02535
USPC 438/478

(57) ABSTRACT

Methods of depositing silicon germanium tin (SiGeSn) layer on a substrate are disclosed herein. In some embodiments, a method may include co-flowing a silicon source, a germanium source, and a tin source comprising a tin halide to a process chamber at a temperature of about 450 degrees Celsius or below and a pressure of about 100 Torr or below to deposit the SiGeSn layer on a first surface of the substrate. In some embodiments, the tin halide comprises tin tetrachloride (SnCl₄).

### CROSS-REFERENCE TO RELATED APPLICATIONS

This application claims benefit of U.S. provisional patent application Ser. No. 61/586,181, filed Jan. 13, 2012, which is herein incorporated by reference.

### FIELD

Embodiments of the present invention generally relate to methods for depositing layers on substrates, and more specifically, to methods for depositing a silicon germanium tin (SiGeSn) layer on a substrate.

### BACKGROUND

Ternary alloys of Group IV elements, such as silicon germanium tin (SiGeSn) have a band structure that may depend on the composition of the alloy. The tuning of the composition of component elements, such as germanium (Ge) or tin (Sn) may allow for the independent tuning of the band structure and strain in the alloy. For example, tuning of the band structure or strain in the alloy may be used to improve electron mobility, adjust junction resistance or other suitable aspects associated with forming electronic devices from semiconducting materials. Unfortunately, conventional tin sources used to form an SiGeSn alloy are either rare or unstable or both. An exemplary tin source may be a tin hydride or the like. The instability of the tin source may result in poor alloy quality, such as not having the appropriate band structure or strain due to failed incorporation of tin (Sn) from the tin source, and/or lack of manufacturing reproducibility.

Accordingly, the present invention provides improved methods of depositing a SiGeSn layer on a substrate.

### SUMMARY

Methods of depositing silicon germanium tin (SiGeSn) layer on a substrate are disclosed herein. In some embodiments, a method may include co-flowing a silicon source, a germanium source, and a tin source comprising a tin halide to a process chamber at a temperature of about 450 degrees Celsius or below and a pressure of about 100 Torr or below to deposit the SiGeSn layer on a first surface of the substrate. In some embodiments, the tin halide comprises tin tetrachloride (SnCl₄).

In some embodiments, a computer readable medium may be provided having instructions stored thereon that, when executed, cause a method of depositing silicon germanium tin (SiGeSn) layer on a substrate to be performed in a process chamber. The method may include any embodiments of the methods disclosed herein.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart of a method for depositing a silicon germanium tin (SiGeSn) layer on a substrate in accordance with some embodiments of the present invention.

FIGS. 2A-D respectively depict the stages of fabrication of a silicon germanium tin (SiGeSn) layer on a substrate in accordance with some embodiments of the present invention.

FIG. 3 depicts an apparatus for depositing a layer on a substrate in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods for depositing a silicon germanium tin (SiGeSn) layer on a substrate are disclosed herein. The inventive methods advantageously allow for improved layer quality, such achieving a desired band structure or layer strain and improved manufacturing reproducibility. Other and further advantages of the inventive methods are discussed below.

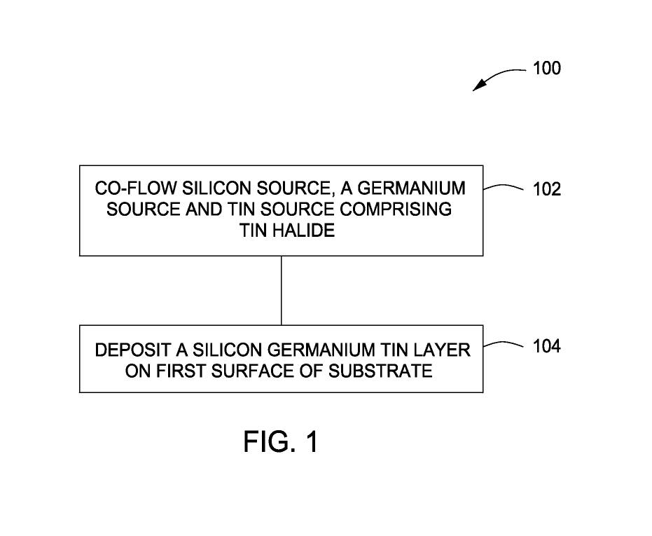

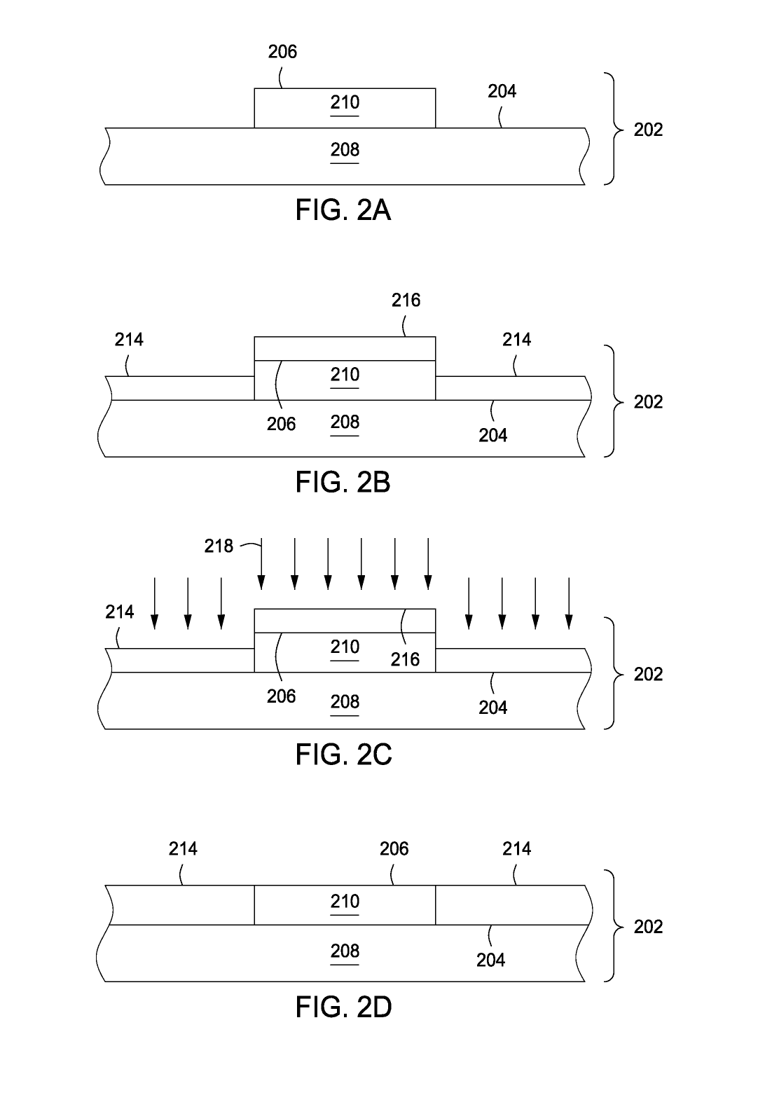

FIG. 1 depicts a flow chart for a method 100 of depositing a SiGeSn layer on a substrate in accordance with some embodiments of the present invention. The method 100 is described below in accordance with stages of fabrication of a SiGeSn layer on a substrate as illustrated in FIGS. 2A-D in accordance with some embodiments of the invention. As illustrated in FIG. 2A, a substrate 202 may include a first surface 204 and a second surface 206. In some embodiments, the first surface 204 may be an exposed surface of a substrate 208 as shown. For example, the substrate 208 may include one or more silicon (Si), germanium (Ge), tin (Sn), or other suitable substrate materials. For example, the substrate may be a silicon substrate, a germanium substrate, a silicon-germanium (SiGe) substrate, a germanium-tin substrate (GeSn), or the like. In some embodiments, the second surface 206 may be part of a dielectric layer, such as a dielectric layer 210 disposed on the substrate 208. For example, the dielectric layer may comprise one or more of silicon oxide (SiO₂), silicon nitride (Si₃N₄), or other suitable materials than may be used to form a dielectric layer.

The embodiments of the substrate 202 as illustrated in FIG. 2A are merely exemplary and other suitable configurations of the substrate 202 are possible. For example, as illustrated in FIG. 2A, the substrate 202 may be part of a partially formed device, such as a metal-oxide-semiconductor field effect transistor (MOSFET). However, other devices, such as fin field effect transistors (FinFETs) or the like may be used with the inventive methods disclosed herein. The SiGeSn layer formed herein may be used in source/drain regions or channel regions of transistor devices, as opto-electronic bandgap materials, in complementary metal oxide semiconductor (CMOS) applications or the like.

The method 100 generally begins at 102 by co-flowing a silicon source, a germanium source, and a tin source comprising a tin halide. For example, the silicon source may include one or more silanes (SiₓH_{y}), wherein, for example, y=2x+2, such as disilane (Si₂H₆), trisilane (Si₃H₈), neopentasilane (Si₅H₁₂), or other suitable higher order silanes. The silicon source may include chlorinated silanes, for example, having the generic formula SiₓH_{y}Cl_{z}, y+z=2x+2, x=1, 2, . . . Exemplary chlorinated silanes may include dichlorosilane (SiH₂Cl₂), tetrachlorosilane (SiCl₄) or the like. In some embodiments, such as at temperatures of about 450 degrees Celsius or below, for example, ranging from about 300 to about 450 degrees Celsius, and at higher desired tin concentrations in the SiGeSn layer, for example such as about 8 to about 9 percent tin, higher order silanes such as trisilane and/or neopentasilane may be needed as the silicon sources. For example, the germanium source may include one or more germanes (GeₓH_{y}), wherein, for example, y=2x+2, such as digermane (Ge₂H₆), trigermane (Ge₃H₈), higher order germanium hydrides, or the like. The germanium source may be chlorinated germanes, for example, having the generic formula GeₓH_{y}Cl_{z}, y+z=2x+2, x=1, 2, . . . Exemplary chlorinated germanes may include germanium tetrachloride (GeCl₄) or the like. The tin source may include a tin halide, such as one or more tin chlorides (SnCl₁₋₄). In some embodiments, the tin source may comprise tin tetrachloride (SnCl₄). Using a tin halide as a tin source as compared to rare and unstable tin sources as discussed above may provide improved layer quality, manufacturability and the like as discussed above.

The tin halide may be a tin halide gas, as discussed above, or an organometallic chloride having the formula RₓSnCl_{y}, where R is methyl or t-butyl, x is 1 or 2, and y is 2 or 3. The tin halide may be provided to the processing chamber at any suitable flow rate, for example, such as a flow rate between about 0.1 sccm and about 300 sccm, such as between about 1 sccm and about 200 sccm, or about 10 sccm. The tin halide may also be mixed with a carrier gas to achieve a desired space velocity and/or mixing performance in a processing chamber. The tin halide may be sourced from a solid or liquid source of tin halide crystals, or solid sublimed into a flowing carrier gas stream, or liquid evaporated into a flowing carrier gas stream, such as a carrier gas stream including one or more of nitrogen (N₂), hydrogen (H₂), argon (Ar), or helium (He), or the tin halide may be generated by passing a halogen gas, optionally with one of the above carrier gases, over a solid tin in a contacting chamber to perform the reaction Sn+2Cl₂→SnCl₄. The contacting chamber is discussed in accordance with an apparatus 300 below and may be adjacent to the processing chamber, coupled thereto by a conduit which is preferably short to reduce the possibility of tin halide particles depositing in the conduit.

In some embodiments, a second gas, such as one or more of hydrogen (H₂), nitrogen (N₂), helium (He), argon (Ar), or the like may be co-flowed with any one or more of the silicon, germanium, and tin sources. In some embodiments, the second gas may be used to liberate silicon, germanium, and/or tin from the silicon, germanium, and/or tin sources for deposition. In some embodiments, the second gas may be used as a carrier gas to achieve a desired flow velocity of the silicon, germanium, and/or tin sources. For example, a higher flow velocity may be used to improve uniformity of a silicon-germanium-tin (SiGeSn) layer being formed.

The silicon, germanium, and tin sources may be co-flowed at any suitable ratios to produce a SiGeSn layer (e.g., a SiGeSn layer 214 as discussed below) having a general stoichiometric ratio of Si_{(1-x-y)}GeₓSn_{y}, where 0<x,y<1 and 0<x+y<1. The tuning of x and y may allow the tuning of band structure or strain in the SiGeSn layer without affecting the other property. The silicon, germanium, and tin sources may be co-flowed at temperatures of about 450 degrees Celsius or below, for example ranging from about 300 to about 450 degrees Celsius. The silicon, germanium, and tin sources may be co-flowed at pressures of about 100 Torr or below, or for example, ranging from about 5 to about 100 Torr. A higher concentration of tin in the SiGeSn layer may be achieved at lower temperatures in the range. As discussed above, at lower temperatures in the range, higher order silanes may be required. For example, at higher temperatures in the range, and when the desired concentration of tin is about 1 to about 2 percent, lower order silanes, such as disilane may be utilized.

Optionally, addition sources may be co-flowed with the silicon, germanium, and tin sources, for example, such as dopant sources. Typical dopants may include one or more of boron (B), phosphorus (P), arsenic (As) or the like. For example, dopants sources may include diborane (B₂H₆), phosphine (PH₃), arsine (AsH₃) or the like. Additional dopants and/or dopant sources may be utilized.

At 104, a SiGeSn layer 214 may be deposited on the first surface 204 of the substrate 208 by co-flowing the silicon, germanium, and tin sources as discussed above. For example, the SiGeSn layer 214 may be deposited by any suitable deposition method, such as reduced pressure chemical vapor deposition (CVD) or any other suitable deposition method. The SiGeSn layer 214 may be deposited to any desired thickness, such as about 0.001 to about 10 microns.

As illustrated in FIG. 2B, a portion 216 of the SiGeSn layer 214 may be deposited on the second surface 206 of the dielectric layer 210. In some embodiments, as illustrated in FIG. 2C, the SiGeSn layer 214 may be etched using an etchant 218 to selectively remove the portion 216 of the SiGeSn layer 214 that has deposited on the second surface 206 of the dielectric layer 210. For example, the deposition and etching of the SiGeSn layer 214 may be performed simultaneously or alternated. The etchant 218 may comprise at least one or chlorine (Cl) or bromine (Br) and, optionally, hydrogen (H). For example, in some embodiments, the etchant may be at least one of hydrogen chloride (HCl), hydrogen bromide (HBr), chlorine (Cl₂), or bromine (Br₂).

FIG. 2D illustrated the SiGeSn layer 214 grown to a desired thickness wherein the SiGeSn layer 214 is not present on the second surface 206 of the dielectric layer 210 after the selective etching process as discussed above.

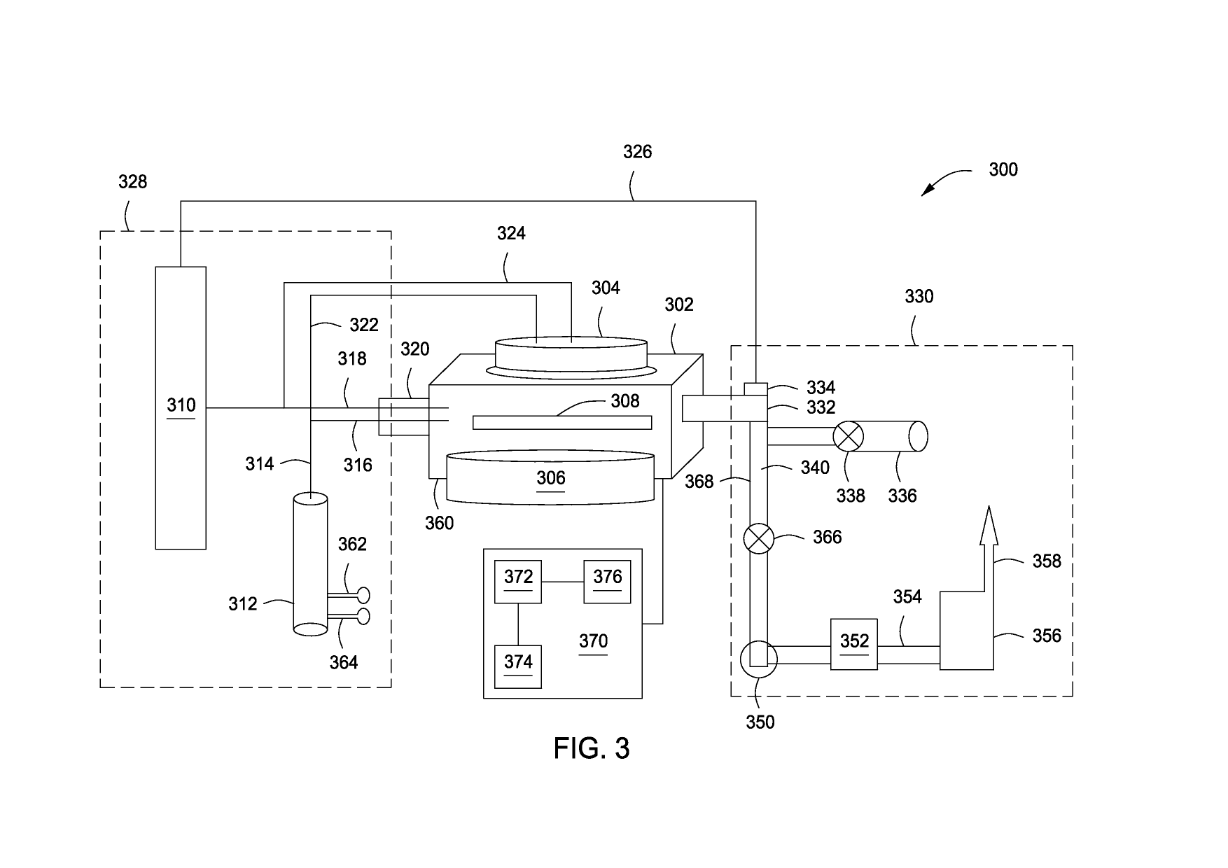

FIG. 3 is a schematic diagram of an apparatus 300 according to another embodiment. The apparatus 300 is useable for practicing the methods described herein for forming a SiGeSn layer. A processing chamber 302 has a substrate support 308, which may be a rotating substrate support, disposed in an interior thereof. A heat source 306 is disposed facing one side of the substrate support 308. Alternately, a heat source may be embedded in the substrate support 308. A chamber with a heated substrate support as described in commonly assigned U.S. Pat. No. 7,172,792, entitled “Method for forming a high quality low temperature silicon nitride film”, issued Feb. 6, 2007, may be adapted to practice the methods described herein. A chamber with a lamp heating module as described in commonly assigned U.S. Patent Publication 2008/0072820, entitled “Modular CVD Epi 300 mm Reactor”, published Mar. 27, 2008, may also be adapted to practice the methods described herein. An Epi™ 300 mm reactor or a 300 mm xGen™ chamber, both available from Applied Materials, Inc., of Santa Clara, Calif., may be adapted to make and use embodiments described herein. The processing chamber 302 may have a showerhead 304 for gas entry into the chamber. Alternately, or in combination, gas may be provided to the processing chamber through a side entry 320 coupled to a side wall 360 of the chamber 302.

A feed system 328, including a chemical delivery system 310 and a metal precursor contact chamber 312, is coupled to the chamber 302 through a variety of conduits. A first conduit 322 and a second conduit 324 may couple the feed system 328 to the optional showerhead 304. The showerhead 304 may be a dual-pathway showerhead to prevent mixing of the sources (e.g., silicon, germanium, and/or tin sources) prior to entry into the chamber 302. An exemplary dual-pathway showerhead is described in commonly assigned U.S. Pat. No. 6,983,892, entitled “Gas distribution showerhead for semiconductor processing”, issued Jan. 10, 2006.

Alternately, or additionally, cross-flow gas injection may be practiced by providing first and second cross-flow gas conduits 316 and 318 to the side entry point 320. An example of a cross-flow injection configuration is described in U.S. Pat. No. 6,500,734. The apparatus 300 may contain both a showerhead configuration and a cross-flow injection configuration, optionally with an adjustable gas flow ratio between the two, or only one or the other configuration.

The chemical delivery system 310 delivers silicon, germanium, or tin sources, optionally with carrier gases such as nitrogen (N₂) and/or hydrogen (H₂), to the chamber 302. The chemical delivery system 310 may also deliver deposition or selectivity control species to the chamber 302. The chemical delivery system 310 may include liquid or gaseous sources and controls (not shown), which may be configured in a gas panel.

A contact chamber 312 may be coupled to either the side entry point 320 or the showerhead 304 by a conduit 314 disposed to carry a metal precursor to the chamber 302. Conduits 314, 316, and 322 may be heated to a temperature between about 50° C. and about 200° C. to control or prevent condensation of the metal precursor therein. The contact chamber 312 typically contains a bed of solid metal or metal halide crystals. The metal halide crystals (e.g., a tin halide) may be sublimed into a carrier gas provided through one or both of the gas feed conduits 362 and 364. The solid metal may be contacted with a halogen gas source provided through one or both of the gas feed conduits 362 and 364. In one embodiment, a halogen gas source is provided through a first gas feed conduit 362 while a carrier gas is provided through a second gas feed conduit 364. The gases, either for subliming or reacting, may be flowed through a powdered metal or metal halide fluidized bed to enhance contacting. A mesh strainer or filter may be used to prevent entrainment of particles into the chamber 302. Alternately, the gases may flow across a fixed solid metal or metal halide bed.

An exhaust system 330 is coupled to the chamber 302. The exhaust system 330 may be coupled to the chamber at any convenient location, which may depend on the location of the gas entry into the chamber. For gas entry through the showerhead 304, the exhaust system may be coupled to a bottom wall of the chamber, around the heat source 306, for example, by one or more portals or through an annular opening. An annular manifold may be disposed near an edge of the substrate support and coupled to the exhaust system 330 in some embodiments. For cross-flow embodiments, the exhaust system 330 may be coupled to a side wall of the chamber opposite the side entry point 320.

An exhaust conduit 340 couples an exhaust cap 332 to a vacuum pump 352 through a throttle valve 366. A jacket 368 encompasses the exhaust conduit 340 and throttle valve 366 from the exhaust cap 332 to an inlet 350 of the vacuum pump 352. The jacket 368 enables thermal control of the exhaust conduit 340 to prevent condensation of exhaust species in the line. Any heating medium, such as steam, or hot air, water, or other hot fluid, may be used to maintain the exhaust conduit at a temperature above a dew point of the exhaust gas. Alternately, the jacket may include resistive heating elements (i.e. an electric blanket). A condensation trap 336 may be coupled to the exhaust conduit 340 by a valve 338, if desired, to further enhance trapping of any condensates in the exhaust system 330. The vacuum pump 352 pays off to an abatement system 356 through an abatement conduit 354, which is typically not heated or jacketed, and cleaned gas exhausted at 358. To further reduce wetting or nucleation in the exhaust conduit 340, the exhaust conduit 340 may be coated with quartz or with an inert polymer material.

Plasma or ultraviolet activated cleaning agents may be coupled into the exhaust system 330 by active source 334, which may be coupled to a microwave or RF chamber for generating active cleaning species. A cleaning gas line 326 may provide cleaning gases from the chemical delivery system 310 to the exhaust conduit 340, proceeding through the active source 334, if desired. Use of active species for cleaning allows cleaning to proceed at reduced temperatures.

A method for cleaning a chamber used to perform the methods described herein, such as the chamber 302, may include providing a halogen gas to the chamber, converting residues to volatile halides. Temperature of the chamber is typically maintained below about 600° C. during cleaning, and metal deposits are converted to MClₓ. The halogen gas may be chlorine gas, fluorine gas, HCl, or HF. The chamber may be heated to an extent that separate heating of the exhaust conduit is not needed, especially if the exhaust conduit is insulated. Alternately, chamber temperature may be kept below about 400° C., if desired, and the exhaust conduit 340 heated to prevent condensation.

A controller 370 may be provided and coupled to various components of the apparatus 300 to control the operation thereof. The controller 370 includes a central processing unit (CPU) 372, a memory 374, and support circuits 376. The controller 370 may control the apparatus 300 directly, or via computers (or controllers) associated with particular process chamber and/or support system components. The controller 370 may be one of any form of general-purpose computer processor that can be used in an industrial setting for controlling various chambers and sub-processors. The memory, or computer readable medium, 374 of the controller 370 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 376 are coupled to the CPU 372 for supporting the processor in a conventional manner. These circuits include cache, power supplies, clock circuits, input/output circuitry and subsystems, and the like. Inventive methods as described herein may be stored in the memory 374 as software routine that may be executed or invoked to control the operation of the process chamber 300 in the manner described herein. The software routine may also be stored and/or executed by a second CPU (not shown) that is remotely located from the hardware being controlled by the CPU 372.

While the foregoing is directed to embodiments of the present invention, other and further embodiments of the invention may be devised without departing from the basic scope thereof.

1. A method of depositing silicon germanium tin (SiGeSn) layer on a substrate, comprising:
co-flowing a silicon source, a germanium source, and a tin source comprising a tin halide to a process chamber at a temperature of about 450 degrees Celsius or below and a pressure of about 100 Torr or below to deposit the SiGeSn layer on a first surface of the substrate.

2. The method of claim 1, wherein the tin halide comprises tin tetrachloride (SnCl₄).

3. The method of claim 1, further comprising:
co-flowing a second gas with one or more of the silicon, germanium, and tin sources.

4. The method of claim 3, wherein the second gas comprises at least one of hydrogen (H₂), nitrogen (N₂), argon (Ar), or helium (He).

5. The method of claim 1, wherein the silicon source comprises one or more silanes or chlorinated silanes.

6. The method of claim 1, wherein the germanium source comprises one or more germanes or chlorinated germanes.

7. The method of claim 1, further comprising:
etching the SiGeSn layer to selectively remove a portion of the SiGeSn layer from a second surface of a dielectric layer disposed on the substrate adjacent to the first surface of the substrate.

8. The method of claim 7, wherein depositing the SiGeSn layer and etching the SiGeSn layer is performed simultaneously.

9. The method of claim 1, further comprising:
co-flowing a dopant source with one or more of the silicon, germanium, and tin sources.

10. The method of claim 1, wherein a concentration of tin (Sn) in the SiGeSn layer is about 8 to about 9% and wherein the silicon source gas comprises one or more silanes or chlorinated silanes.

11. A computer readable medium having instructions stored thereon that, when executed, cause a method of depositing silicon germanium tin (SiGeSn) layer on a substrate to be performed in a process chamber, the method comprising:
co-flowing a silicon source, a germanium source, and a tin source comprising a tin halide to a process chamber at a temperature of about 450 degrees Celsius or below and a pressure of about 100 Torr or below to deposit the SiGeSn layer on a first surface of the substrate.

12. The computer readable medium of claim 10, wherein the tin halide comprises tin tetrachloride (SnCl₄).

13. The computer readable medium of claim 10, further comprising:
co-flowing a second gas with one or more of the silicon, germanium and tin sources.

14. The computer readable medium of claim 13, wherein the second gas comprises at least one of hydrogen (H₂), nitrogen (N₂), argon (Ar), or helium (He).

15. The computer readable medium of claim 10, wherein the silicon source comprises one or more silicon hydrides or chlorinated silicon hydrides.

16. The computer readable medium of claim 10, wherein the germanium source comprises one or more germanium hydrides or chlorinated germanium hydrides.

17. The computer readable medium of claim 10, further comprising:
etching the SiGeSn layer to selectively remove a portion of the SiGeSn layer from a second surface of a dielectric layer disposed on the substrate adjacent to the first surface of the substrate.

18. The computer readable medium of claim 17, wherein depositing the SiGeSn layer and etching the SiGeSn layer is performed simultaneously.

19. The computer readable medium of claim 10, further comprising:
co-flowing a dopant source with one or more of the silicon, germanium, and tin sources.

20. The computer readable medium of claim 10, wherein a concentration of tin in the SiGeSn layer is about 8 to about 9% and wherein the silicon source gas comprises one or more silanes or chlorinated silanes.
